(19) United States
(12) Patent Application Publication
(10) Pub. No.: US 2012/0181651 A1
(43) Pub. Date: Jul. 19, 2012

(54) Temperature Sensor Based on Magnetic Tunneling Junction Device

(75) Inventor: Yanfeng Jiang, Beijing (CN)

(73) Assignee: NORTH CHINA UNIVERSITY OF TECHNOLOGY, Beijing (CN)

(21) Appl. No.: 13/349,712

(22) Filed: Jan. 13, 2012

(30) Foreign Application Priority Data
Jan. 14, 2011 (CN) 201110008191.2

(51) Int. Cl. H01L 29/66

(52) U.S. Cl. 257/467; 257/E29.347

(57) ABSTRACT

A temperature sensor, based on magnetic tunneling junction (MTJ) device, includes an MTJ device, a PMOS device and an analog switch. Source electrode of the PMOS device is connected to a power supply; drain electrode of the PMOS device is connected to an input terminal of the MTJ device and is connected to the voltage output terminal of the temperature sensor; an output terminal of the MTJ device is connected to a ground or a circuit via the analog switch; drain electrode of the PMOS device is short circuited with gate electrode of the PMOS device. A negative input terminal of an operational amplifier is connected to the voltage output terminal and a positive input terminal of the operational amplifier is connected to a reference voltage. The sensor is compatible with CMOS process and able to simultaneously perform functions such as temperature detection, over-temperature protection and over-current protection.

### CROSS-REFERENCE TO RELATED APPLICATIONS

This application claims priority to Chinese Patent Application No. 2011110008191.2, filed on Jan. 14, 2011, the disclosure of which is herein incorporated herein by reference.

### FIELD OF THE INVENTION

The field relates to a temperature sensor, particularly to a temperature sensor based on magnetic tunneling junction device.

### BACKGROUND OF THE INVENTION

There are a variety of available temperature sensors. Some are designed according to the PN junction theory; some are designed according to the threshold voltage of MOS transistor. However, there are more varistor temperature sensors made on the basis of the characteristic that varistor resistance changes according to the temperature.

Many of the available sensors at least have some of these problems; they cannot simultaneously perform functions such as temperature detection, over-temperature protection and over-current protection.

There remains a continuing need for improved temperature sensors.

### SUMMARY OF THE INVENTION

In one exemplary embodiment, a temperature sensor based on magnetic tunneling junction (MTJ) device, comprises an MTJ device, a PMOS device and an analog switch. In this embodiment, a source electrode of the PMOS device is connected to a power supply, a drain electrode of the PMOS device is connected to the input terminal of the MTJ device and is connected to a voltage output terminal of the temperature sensor.

Additionally, the output terminal of the MTJ device is connected to the ground or a circuit via the analog switch, and the drain electrode of the PMOS device is short circuited with the gate electrode of the PMOS device.

### BRIEF DESCRIPTION OF THE FIGURES

Further features and advantages of the invention will become apparent when the following detailed description is read in view of the drawing figures, in which:

FIG. 1 is a schematic electrical diagram of exemplary embodiments of the temperature sensor based on magnetic tunneling junction device;

FIG. 2 is a graph of output voltage versus temperature for the PMOS devices with different dimensions in specific embodiments;

FIG. 3 is a schematic electrical diagram of a preferred embodiment of the over-temperature protection circuit based on the MTJ temperature sensor;

FIG. 4 is a graph of measurement results of the sensor in FIG. 3 when it is used for over-temperature protection.

### DETAILED DESCRIPTION OF THE INVENTION

The examples and drawings provided in the detailed description are merely examples, which should not be used to limit the scope of the claims in any claim construction or interpretation.

The following terms used throughout the specification are abbreviations. “MTJ” stands for “magnetic tunnel junction.” “CMOS stands for “complementary metal-oxide-semiconductor field-effect transistor.” “NMOS stands for “n-channel MOSFET (metal-oxide-semiconductor field-effect transistor). “PMOS stands for “p-channel MOSFET (metal-oxide-semiconductor field-effect transistor).

An object of the invention, among many, is to provide a temperature sensor based on magnetic tunneling junction (MTJ) device. The sensor is compatible with CMOS process and is able to simultaneously perform the functions such as temperature detection, over-temperature protection and over-current protection.

An exemplary temperature sensor based on magnetic tunneling junction device, includes an MTJ device, a PMOS device and an analog switch, where the source electrode of the PMOS device is connected to a power supply; the drain electrode of the PMOS device is connected to the input terminal of the MTJ device and is connected to the voltage output terminal of the temperature sensor; the output terminal of the MTJ device is connected to the ground or a circuit via the analog switch; and the drain electrode of the PMOS device is short circuited with the gate electrode of the PMOS device.

The exemplary temperature sensor also includes an operational amplifier. The negative input terminal of the operational amplifier is connected to the voltage output terminal; the positive input terminal of the operational amplifier is provided with a reference voltage. Therefore, an over-temperature protection circuit is formed when the voltage is being detected.

The temperature sensor also includes an NMOS device. The source electrodes and the drain electrodes of the NMOS device and the PMOS device are connected with each other respectively, and the drain electrode of the NMOS device is short circuited with the gate electrode of the NMOS device.

The MTJ (Magnetic Tunneling Junction) device can be an STT-MTJ (Spin-Transfer-Torque Magnetic Tunnel Junction) device or an MTJ device of another type.

In order to protect an integrated circuit from damage of high temperature which causes the degradation of its circuit performance, and even failure in certain cases, a temperature sensor is normally integrated within the integrated circuit. The sensor is required to detect the temperature of the integrated circuit and shut down power supply in time when the integrated circuit is faced with over-temperature or short circuit, for protection purpose.

An exemplary temperature sensor is based on magnetic tunneling junction (MTJ) device. In one example, the temperature sensor is made by utilizing the magnetic tunneling junction device, and this sensor is compatible with CMOS process and able to simultaneously perform the functions such as temperature detection, over-temperature protection and over-current protection.

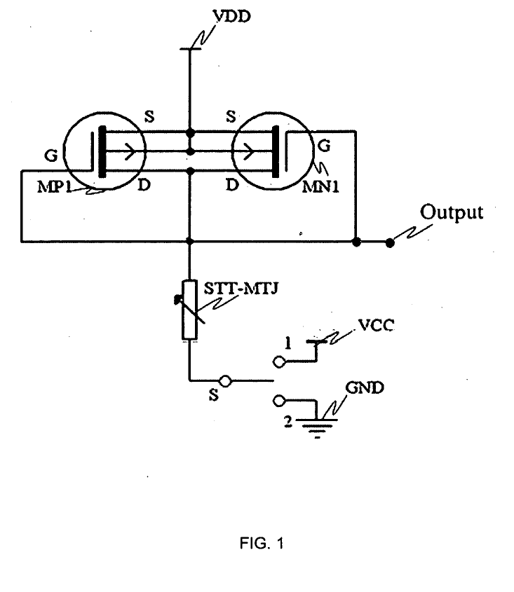

The structure principle of exemplary embodiments is shown in FIG. 1. In FIG. 1, the sensor includes an STT-MTJ device, a PMOS device MP1, an NMOS device MN1 and an analog switch S. The resistance of the MTJ-device varies with temperature in anti-parallel state, so the MTJ device shall be in anti-parallel state during the temperature detection.

The MTJ device is in anti-parallel state at the beginning of temperature detection. The gate electrode G of the PMOS device MP1 is short circuited with the drain electrode D of the PMOS device MP1, so the device is always in a saturation state, in this example.

Therefore, a circuit for conducting current is constructed between the power supply VDD and the ground GND after the analog switch S is connected with the contact point 2; in this case, MP1 and MTJ device compose a single-stage CMOS amplifier. On the premise that the length-to-width ratio of MP1 is fixed, the output voltage of this sensor varies with the resistance of the MTJ device; a temperature change causes the resistance of the MTJ device to change, so the output voltage also changes. therefore, the temperature measurement function of this sensor is that it can measure the temperature through measuring the corresponding output voltage.

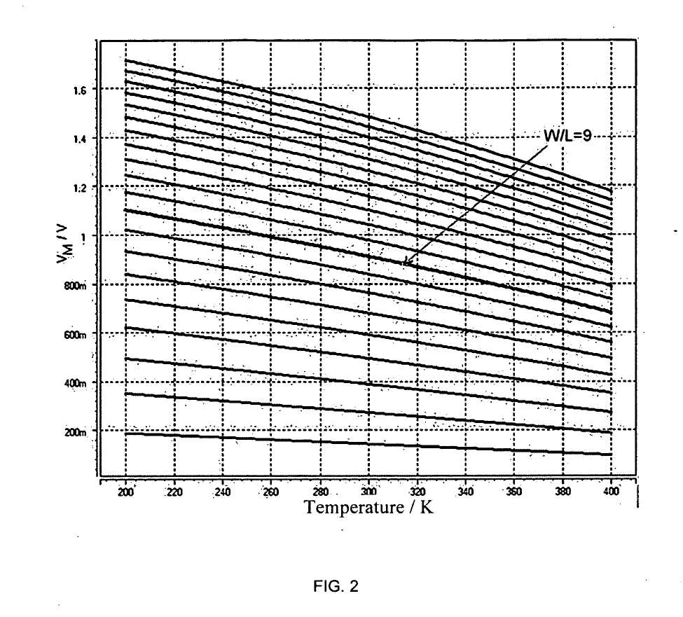

FIG. 2 is a graph of output voltage versus temperature for the PMOS devices with different dimensions. The figure indicates that each different curve corresponds to different dimension of the PMOS device, and specifically, the curves from top to bottom respectively correspond to the length-to-width ratios from 1 to 20. The figure shows that there are slight differences of the change rate of output voltage versus temperature between the different device dimensions. The user can choose the corresponding length-to-width ratio according to the different requirements of an interface circuit. An interface circuit is connected to the output and is not shown. For example, generally the change rate of output voltage versus temperature of a PN junction is −2 mV/K in the circuit of a traditional PN junction sensor, so the backend processing circuit normally corresponds to this value. In the course of the design of the MTJ sensor, the circuit whose length to width ratio is 9 can be adopted. The corresponding change rate of this circuit is −2 mV/K and accords with the old custom, so the circuit with proven backend can be directly adopted.

Current flows from free layer to fixed layer during a temperature measurement, and the current is negative current for the MTJ device. The conductance of the device is increased as temperature rises, so the current is also increased. For MTJ device, there is a parameter, representing the current density for MTJ's transfer from antiparallel to parallel state, of:

J_{C}^{AP→P},

where AP represents anti-parallel state, P represents a parallel state, C represents current and J represents current density. MTJ will flip into parallel state after that the current density exceeds the parameter.

The equivalent resistance of MTJ will suddenly drop after that MTJ flip into parallel state, and cause the output voltage drop in FIG. 1. Therefore, a necessary detection circuit can be added to the sensor structure in FIG. 1.

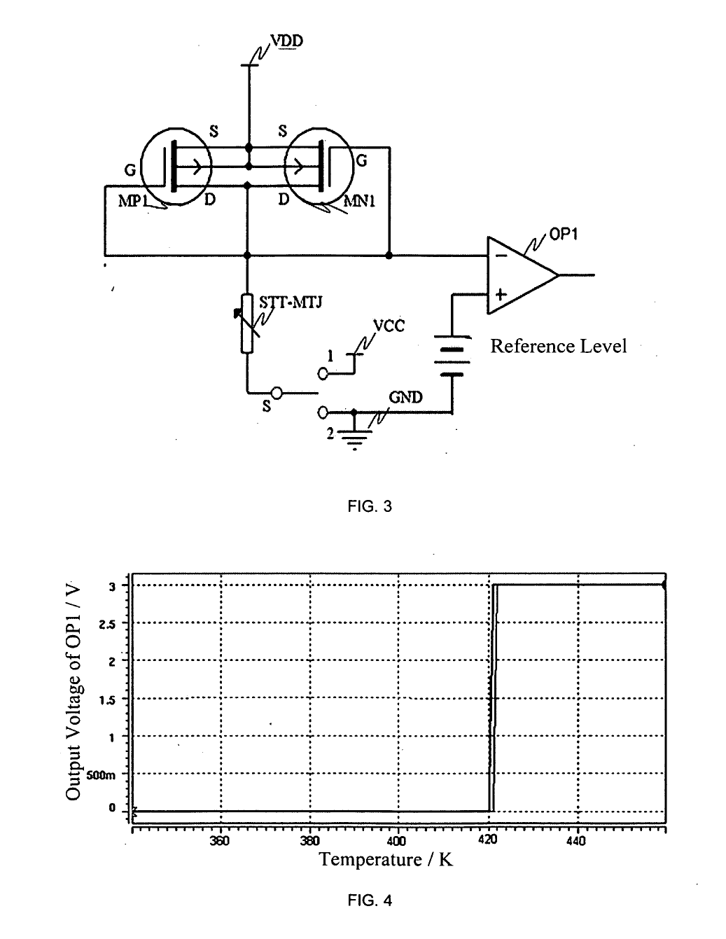

As shown in FIG. 3, the output of the sensor is connected to the negative input terminal of the operational amplifier OP1, and the positive input terminal of OP1 is connected to a reference level. Generally, the output which is set by a user is always higher than the reference level, so the output of OP1 is always low level; when MTJ is flipping into high level as the result of very high temperature, OP1 will be activated and output a high level, so the resulting enable signal will shut off external power supply.

FIG. 4 shows an example of measurement result of over-temperature protection. The figure indicates that the protection circuit immediately operates without any delay or thermal oscillation in any form while the temperature is higher than 420 K. The figure also indicates that the reference level is not strictly restricted because the conductances are very different between parallel state and anti-parallel state of MTJ device. Therefore, the setting of the reference level is only needed to be in a certain range.

From the examples provided, it is evident that the exemplary temperature sensor based on magnetic tunneling junction device is compatible with CMOS process and able to simultaneously perform the functions such as temperature detection, over-temperature protection and over-current protection since it comprises an MTJ device, a PMOS device and an analog switch, and the source electrode of the PMOS device is connected to a power supply, the drain electrode is connected to the input terminal of the MTJ device and is connected to the voltage output terminal, the output terminal of the MTJ device is connected to the ground or a circuit via the analog switch, and the drain electrode of the PMOS device is short circuited with the gate electrode.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A temperature sensor based on magnetic tunneling junction (MTJ) device, comprising an MTJ device, a PMOS device and an analog switch, wherein a source electrode of the PMOS device is connected to a power supply, a drain electrode of the PMOS device is connected to an input terminal of the MTJ device and is also connected to a voltage output terminal of the temperature sensor, an output terminal of the MTJ device is connected to a ground or a circuit via the analog switch, and a drain electrode of the PMOS device is short circuited with a gate electrode of the PMOS device.

2. The temperature sensor based of claim 1, further comprising an operational amplifier, wherein a negative input terminal of the operational amplifier is connected to the voltage output terminal of the temperature sensor, and a positive input terminal of the operational amplifier is provided with a reference voltage.

3. The temperature sensor of claim 1, further comprising an NMOS device, wherein source electrodes and drain electrodes of the NMOS device and the PMOS device are connected with each other, respectively, and a drain electrode of the NMOS device is short circuited with a gate electrode of the NMOS device.

4. The temperature sensor of claim 3, wherein the MTJ device is a STT-MTJ device.

5. The temperature sensor of claim 2, further comprising an NMOS device, wherein source electrodes and drain electrodes of the NMOS device and the PMOS device are connected with each other, respectively, and a drain electrode of the NMOS device is short circuited with a gate electrode of the NMOS device.

6. The temperature sensor of claim 5, wherein the MTJ device is a STT-MTJ device.
